(19) United States
(12) Patent Application Publication
(10) Pub. No.: US 2012/0294790 A1
(43) Pub. Date: Nov. 22, 2012

(54) SILICON CARBIDE SUBSTRATE, SILICON CARBIDE INGOT, AND METHODS FOR MANUFACTURING SILICON CARBIDE SUBSTRATE AND SILICON CARBIDE INGOT

(75) Inventors: Makoto SASAKI, Itami-shi (JP); Taro Nishiguchi, Itami-shi (JP)

(73) Assignee: SUMITOMO ELECTRIC INDUSTRIES, LTD., Osaka-shi (JP)

(21) Appl. No.: 13/472,922

(22) Filed: May 16, 2012

Related U.S. Application Data
(60) Provisional application No. 61/488,284, filed on May 20, 2011.

(30) Foreign Application Priority Data
May 20, 2011 (JP) 2011-113341

(51) Int. Cl. C01B 31/36; B32B 3/10; B32B 3/02; C30B 23/02; B32B 9/04

(52) U.S. Cl. 423/345; 117/106; 428/446; 428/64.1; 428/137

(57) ABSTRACT

A method of manufacturing a silicon carbide ingot having highly uniform characteristics includes a preparation step of preparing a base substrate made of single crystal silicon carbide and having an off angle of 0.1° or more and 10° or less in an off angle direction which is either a <11-20> direction or a <1-100> direction relative to a (0001) plane, and a film formation step of growing a silicon carbide layer on a surface of the base substrate. In the film formation step, a region having a (0001) facet 5 is formed on a surface of the grown silicon carbide layer at an end portion on an upstream side, the upstream side being a side where an angle of intersection between a <0001> direction axis of the base substrate and the surface of the base substrate in the off angle direction is an acute angle.

### BACKGROUND OF THE INVENTION

1. Field of the Invention

The present invention relates to a silicon carbide substrate, a silicon carbide ingot, and methods for manufacturing the silicon carbide substrate and the silicon carbide ingot, and more particularly to a silicon carbide substrate and a silicon carbide ingot with little variation in characteristics such as impurity concentration, and methods for manufacturing the silicon carbide substrate and the silicon carbide ingot.

2. Description of the Background Art

Silicon carbide (SiC) has been conventionally studied as a next-generation semiconductor material to replace silicon (Si). A conventional method of manufacturing a substrate made of silicon carbide is known, in which a silicon carbide single crystal is grown on a seed substrate to form a silicon carbide ingot, and the silicon carbide ingot is sliced to manufacture the substrate. In this method, a seed crystal is prepared with a (0001) plane (so-called c-surface) or a crystallographic plane having an off angle of 10° or less relative to the c-surface as a growth surface, and a silicon carbide single crystal is grown on a growth surface of the seed crystal (see Japanese Patent Laying-Open No. 2004-323348 (hereinafter referred to as Patent Literature 1), for example). When the silicon carbide single crystal is grown on the growth surface of such seed crystal, a (0001) facet is formed near a central portion of a surface of the grown silicon carbide single crystal.

In Patent Literature 1, in order to prevent the formation of a heterogeneous polymorphous crystal or a different surface orientation crystal and to prevent the generation of screw dislocations, a dislocation control seed crystal including a region capable of generating screw dislocations is prepared, and a silicon carbide single crystal is grown on the dislocation control seed crystal. Further, in a step of growing the silicon carbide single crystal in Patent Literature 1, a c-surface facet is formed on a surface of the silicon carbide single crystal, and the silicon carbide single crystal is grown such that the (0001) facet overlaps the screw dislocation generation region. According to Patent Literature 1, the formation of a heterogeneous polymorphous crystal or a different surface orientation crystal and the generation of screw dislocations in the silicon carbide single crystal can be suppressed by growing the silicon carbide single crystal in such a manner as described above. Patent Literature 1 also suggests adjusting a position of the (0001) facet to overlap the screw dislocation generation region by controlling concentration distribution of reactive gas, or by controlling temperature distribution of the seed crystal, in the step of growing the silicon carbide single crystal.

Nitrogen (N) is relatively more readily taken into the (0001) facet on the surface of the silicon carbide single crystal during the crystal growth than into a remaining portion of the surface. Consequently, during the growth of the silicon carbide single crystal, a high concentration nitrogen region having a nitrogen concentration higher than in the remaining region is formed in a portion below the surface on which the (0001) facet has been formed. It is desired that nitrogen concentration in silicon carbide be as uniform as possible in an ingot and a substrate formed from the ingot, because it has an influence on characteristics such as electrical conductivity and light transmission properties of the silicon carbide single crystal. In a silicon carbide ingot formed with a conventional method, however, the arrangement and size of the (0001) facet are not particularly adjusted in order to obtain an ingot and a substrate having uniform nitrogen concentrations. Thus, in the resultant silicon carbide ingot, while the (0001) facet may be arranged in a position close to an end portion of the ingot, the high concentration nitrogen region of a certain size is formed inside the ingot. As a result, the high concentration nitrogen region is arranged in a region having a uniform nitrogen concentration (i.e., region other than the high concentration nitrogen region) in a substrate cut from the ingot. Namely, it has been conventionally difficult to fofin a region having a uniform nitrogen concentration as a large region including a substrate central region in a silicon carbide substrate.

### SUMMARY OF THE INVENTION

The present invention was made to solve such problems, and an object of the present invention is to provide a silicon carbide substrate and a silicon carbide ingot having highly uniform characteristics, and methods for manufacturing the silicon carbide substrate and the silicon carbide ingot.

The present inventors completed the present invention based on detailed studies of crystal growth of silicon carbide. That is, the inventors found that, when a silicon carbide substrate having an off angle of 0.1° or more and 10° or less, more preferably 1° or more and 10° or less, in a prescribed direction (off angle direction) relative to the (0001) plane was used as a base substrate (seed substrate), and a silicon carbide single crystal was grown on a surface of the base substrate, the (0001) facet formed on a growth surface of the grown silicon carbide single crystal could be formed at an end portion of the growth surface, and further the (0001) facet of a sufficiently small size compared to a planar size of the base substrate could be formed, by adjusting the off angle direction and the off angle of the base substrate, and further the processing conditions in a step of growing the crystal. Consequently, in the formed silicon carbide single crystal, a ratio of the portion (high concentration nitrogen region) located below the (0001) facet can be reduced, thereby forming a large region having a relatively low nitrogen concentration. Based on these findings, a method of manufacturing a silicon carbide ingot according to the present invention includes the steps of preparing a base substrate made of single crystal silicon carbide and having an off angle of 0.1° or more and 10° or less, more preferably 1° or more and 10° or less, in an off angle direction which is either a <11-20> direction or a <1-100> direction relative to a (0001) plane, and growing a silicon carbide layer on a surface of the base substrate. In the step of growing a silicon carbide layer, a region having a (0001) facet is formed on a surface of the grown silicon carbide layer at an end portion on an upstream side, the upstream side being a side where an angle of intersection between a <0001> direction axis of the base substrate and the surface of the base substrate in the off angle direction is an acute angle.

By forming the (0001) facet into which nitrogen is readily taken at the end portion of the ingot in this manner, a region having a relatively high nitrogen concentration (high concentration nitrogen region located below the (0001) facet) can be arranged at the end portion of the silicon carbide ingot. Thus, a region having a relatively low nitrogen concentration (region other than the high concentration nitrogen region) can be formed as a large region including the central portion of the silicon carbide ingot. Thus, when a silicon carbide substrate is cut from the ingot, the silicon carbide substrate in which the region having a relatively low nitrogen concentration is formed in a large region including the substrate central portion can be readily obtained. Since the region having a relatively low nitrogen concentration (region having a stable nitrogen concentration with little nitrogen taken therein) can be formed in a large region including the substrate central portion in this manner, a semiconductor device can be efficiently formed on the surface of the substrate.

When a silicon carbide substrate is cut from a silicon carbide ingot having a high concentration nitrogen region of a certain size foamed in its central portion, for example, a region having a low nitrogen concentration (low concentration nitrogen region) surrounds the high concentration nitrogen region on the surface of the silicon carbide substrate. Thus, when forming a device on the surface of the silicon carbide substrate in the region having a relatively low nitrogen concentration, the device will be formed in a region other than the high concentration nitrogen region (namely, the device will be formed in a region other than the high concentration nitrogen region and a boundary region between the high concentration nitrogen region and the low concentration nitrogen region), resulting in lowered substrate utilization efficiency. According to the present invention, however, the high concentration nitrogen region is arranged at the end portion of the silicon carbide substrate, and thus the low concentration nitrogen region is formed in the central portion of the surface of the silicon carbide substrate. The device can be formed only in the low concentration nitrogen region, thereby effectively utilizing the substrate.

A silicon carbide ingot according to the present invention is manufactured with the method of manufacturing a silicon carbide ingot described above. In this case, the region having a relatively low nitrogen concentration (region other than the high concentration nitrogen region) can be formed as a large region including the central portion of the silicon carbide ingot. Thus, when a silicon carbide substrate is cut from the silicon carbide ingot, the silicon carbide substrate in which the region having a relatively low nitrogen concentration is formed in a large region including the substrate central portion can be readily obtained.

The method of manufacturing a silicon carbide substrate according to the present invention includes the steps of preparing a silicon carbide ingot using the method of manufacturing a silicon carbide ingot described above, and slicing the silicon carbide ingot.

In this case, in the silicon carbide ingot, the region having a relatively low nitrogen concentration (region other than the high concentration nitrogen region) can be formed as a large region including the central portion of the silicon carbide ingot. Thus, when a silicon carbide substrate is cut from the silicon carbide ingot in the slicing step, the silicon carbide substrate in which the region having a relatively low nitrogen concentration is formed in a large region including the substrate central portion can be readily obtained.

A silicon carbide substrate according to the present invention is manufactured with the method of manufacturing a silicon carbide substrate described above. Consequently, a silicon carbide substrate in which the region having a relatively low nitrogen concentration is formed in a large region including the substrate central portion can be readily obtained.

A method of manufacturing a silicon carbide ingot according to the present invention includes the steps of preparing a base substrate made of single crystal silicon carbide and having an off angle of 0.1° or more and 10° or less, more preferably 1° or more and 10° or less, in an off angle direction which is either a <11-20> direction or a <1-100> direction relative to a (0001) plane, and growing a silicon carbide layer on a surface of the base substrate. In the step of growing a silicon carbide layer, a region having a (0001) facet is formed on a surface of the grown silicon carbide layer at an end portion on an upstream side, the upstream side being a side where an angle of intersection between a <0001> direction axis of the base substrate and the surface of the base substrate in the off angle direction is an acute angle. In the silicon carbide layer after the step of growing a silicon carbide layer, a transmittance of light having a wavelength of 450 nm or more and 500 nm or less per unit thickness through a portion located below the region having the (0001) facet is lower than a transmittance of the same light per unit thickness through a portion other than the portion located below the region having the (0001) facet in the silicon carbide layer.

By forming the (0001) facet into which nitrogen is readily taken at the end portion of the ingot in this manner, a region having a reduced light transmittance due to the nitrogen taken therein from the facet during the growth of the silicon carbide layer is arranged at the end portion of the ingot (portion below the (0001) facet). Thus, the remaining portion including the central portion of the silicon carbide ingot can be foamed as a region having a relatively high light transmittance. Accordingly, when a silicon carbide substrate is cut from the ingot, the silicon carbide substrate in which the region having a relatively high light transmittance is formed in a large region including the substrate central portion can be readily obtained. Since the region having a relatively high light transmittance (region having stable nitrogen concentration and transmittance with little nitrogen taken therein) can be formed in a large region including the substrate central portion in this manner, a semiconductor device can be efficiently formed on the surface of the substrate.

A silicon carbide ingot according to the present invention includes a base substrate made of single crystal silicon carbide and having an off angle of 0.1° or more and 10° or less in an off angle direction which is either a <11-20> direction or a <1-100> direction relative to a (0001) plane, and a silicon carbide layer formed on a surface of the base substrate. A region having a (0001) facet is formed on a surface of the grown silicon carbide layer at an end portion on an upstream side, the upstream side being a side where an angle of intersection between a <0001> direction axis of the base substrate and the surface of the base substrate in the off angle direction is an acute angle.

In the silicon carbide layer of the silicon carbide ingot described above, a portion located below the region having the (0001) facet may be a high concentration nitrogen region having a nitrogen concentration higher than in a portion other than the portion located below the region having the (0001) facet in the silicon carbide layer.

By forming the (0001) facet into which nitrogen is readily taken at the end portion of the ingot in this manner, a region having a relatively high nitrogen concentration (high concentration nitrogen region located below the (0001) facet) can be arranged at the end portion of the silicon carbide ingot. Thus, a region having a relatively low nitrogen concentration (region other than the high concentration nitrogen region) can be formed as a large region including the central portion of the silicon carbide ingot. Thus, when a silicon carbide substrate is cut from the ingot, the silicon carbide substrate in which the region having a relatively low nitrogen concentration is formed in a large region including the substrate central portion can be readily obtained. Since the region having a relatively low nitrogen concentration (region having a stable nitrogen concentration with little nitrogen taken therein) can be formed in a large region including the substrate central portion in this manner, a semiconductor device can be efficiently formed on the surface of the substrate.

A silicon carbide substrate according to the present invention is obtained by slicing the silicon carbide ingot described above. Consequently, the silicon carbide substrate in which the region having a relatively low nitrogen concentration (or region having a high light transmittance) is formed in a large region including the substrate central portion can be readily obtained.

A silicon carbide substrate according to the present invention is obtained by slicing the silicon carbide ingot, after the high concentration nitrogen region was removed from the silicon carbide ingot. By removing the high concentration nitrogen region (region having a low light transmittance) in advance in this manner, the silicon carbide substrate is formed using the silicon carbide ingot including only the region having a nitrogen concentration lower than in the high concentration nitrogen region (region having a light transmittance higher than in the high concentration nitrogen region). Accordingly, the silicon carbide substrate with smaller variation in nitrogen concentration and light transmittance can be obtained.

A silicon carbide substrate according to the present invention includes a high concentration nitrogen region having a nitrogen concentration relatively higher than in a remaining portion formed at one end portion in either a <11-20> direction or a <1-100> direction. The high concentration nitrogen region may be formed at an end portion on an upstream side, the upstream side being a side where an angle of intersection between a <0001> direction axis of the silicon carbide substrate and the surface of the silicon carbide substrate in either the <11-20> direction or the <1-100> direction (off angle direction) is an acute angle. By controlling the arrangement of the (0001) facet in this manner when growing a silicon carbide ingot for forming a silicon carbide substrate, the high concentration nitrogen region can be readily arranged at the end portion of the silicon carbide substrate.

According to the present invention, a silicon carbide ingot and a silicon carbide substrate having highly uniform characteristics such as nitrogen concentration can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart for explaining a method of manufacturing a silicon carbide ingot according to the present invention.

FIG. 2 is a flowchart for explaining a method of manufacturing a silicon carbide substrate according to the present invention.

FIG. 3 is a schematic diagram for explaining an example of a film formation step shown in FIG. 1.

FIG. 4 is a schematic plan view of the silicon carbide ingot according to the present invention.

FIG. 5 is a schematic cross sectional view along the line V-V shown in FIG. 4.

FIG. 6 is a schematic plan view showing a silicon carbide substrate that has been cut from the silicon carbide ingot shown in FIGS. 4 and 5.

FIG. 7 is a schematic cross sectional view of a crystal growth device for performing the film formation step shown in FIG. 1.

FIG. 8 is a schematic plan view showing another example of the silicon carbide substrate according to the present invention.

FIG. 9 is a schematic plan view showing a first variation of the silicon carbide ingot according to the present invention.

FIG. 10 is a schematic plan view showing a silicon carbide substrate that has been cut from the silicon carbide ingot shown in FIG. 9.

FIG. 11 is a schematic plan view showing a variation of the silicon carbide substrate shown in FIG. 10.

FIG. 12 is a schematic plan view showing a second variation of the silicon carbide ingot according to the present invention.

FIG. 13 is a schematic plan view showing a silicon carbide substrate that has been cut from the silicon carbide ingot shown in FIG. 12.

FIG. 14 is a schematic plan view showing a variation of the silicon carbide substrate shown in FIG. 13.

FIG. 15 is a schematic plan view showing a third variation of the silicon carbide ingot according to the present invention.

FIG. 16 is a schematic plan view showing a silicon carbide substrate that has been cut from the silicon carbide ingot shown in FIG. 15.

FIG. 17 is a schematic plan view showing a variation of the silicon carbide substrate shown in FIG. 16.

### DESCRIPTION OF THE PREFERRED EMBODIMENTS

Embodiments of the present invention will be described hereinafter with reference to the drawings. It is noted that the same or corresponding parts are designated by the same reference numerals in the following drawings, and description thereof will not be repeated.

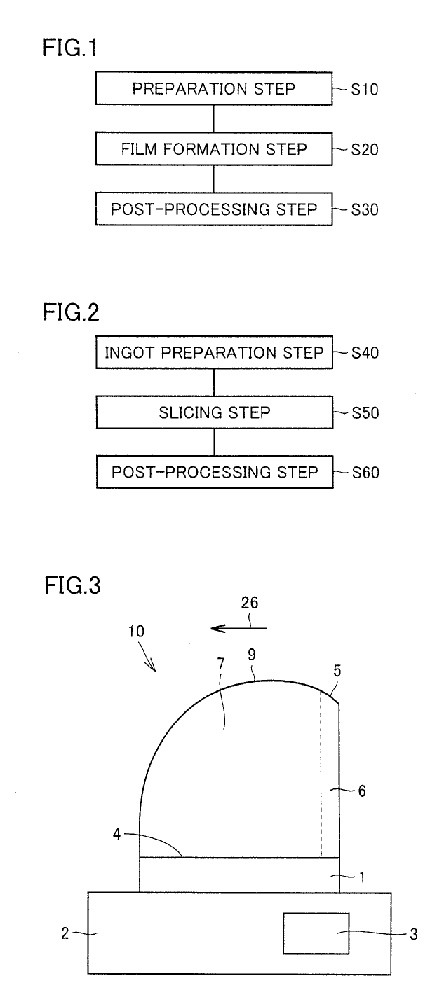

Referring to FIGS. 1 to 8, methods for manufacturing a silicon carbide ingot and a silicon carbide substrate according to the present invention will be described.

As shown in FIG. 1, in a method of manufacturing a silicon carbide ingot (hereinafter also referred to as ingot) according to the present invention, a preparation step (S10) is initially performed. Specifically, a support member 2 such as shown in FIG. 3 is disposed in a processing container of a crystal growth device for forming the ingot, and a base substrate 1 serving as a seed substrate for forming the ingot is mounted on support member 2. Base substrate 1 has a circular planar shape. Base substrate 1 is a silicon carbide (SiC) substrate including a main surface having an off angle set to 0.1° or more and 10° or less, more preferably 0.5° or more and 8° or less, relative to a (0001) plane. In the present specification, an individual plane orientation is indicated with (hkil), and a collective plane orientation including (hkil) and its equivalent plane orientation in terms of crystal geometry is indicated with {hkil}. An individual direction is indicated with [hkil], and a direction including [hkil] and its equivalent direction in terms of crystal geometry is indicated with <hkil>. Although “-” (bar) is commonly attached atop a numeral indicating a negative index in terms of crystal geometry, a negative sign (−) is attached before a numeral indicating an index in the present specification.

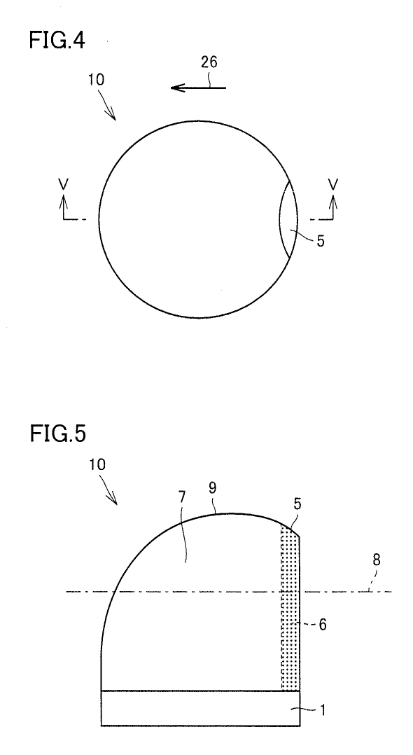

Next, a film formation step (S20) is performed. Specifically, after a pressure and an atmosphere in the processing container of the crystal growth device are set to prescribed conditions, a silicon carbide single crystal is grown on a surface 4 of base substrate 1 with a sublimation recrystallization method or the like while base substrate 1 is heated. A silicon carbide ingot 10 such as shown in FIGS. 3 to 5 is formed in this manner. In this film formation step (S20), a (0001) facet 5 (hereinafter also referred to as facet 5) is formed on a surface of ingot 10. The processing conditions for the film formation step (S20) are set such that facet 5 is arranged at one outer circumferential end portion when seen from an upper surface of ingot 10, as shown in FIG. 4. The processing conditions will be described later.

A region continuing below facet 5 is a high concentration nitrogen region 6 having a nitrogen concentration relatively higher than in a remaining region due to a larger amount of nitrogen taken therein from facet 5 than into the remaining region. That is, during the growth of silicon carbide to form ingot 10, a relatively larger amount of nitrogen is taken into the silicon carbide from facet 5 on the surface of the grown silicon carbide than into the remaining region, high concentration nitrogen region 6 has a nitrogen concentration relatively higher than in a low concentration nitrogen region 7 which is the remaining region.

Facet 5 is positioned at the end portion in an off angle direction indicated with an arrow 26. Any method (processing conditions) can be used to arrange facet 5 at the end portion of ingot 10 in this manner. For example, in a crystal growth device including a crucible 11 and heating coils 12 as shown in FIG. 7, ingot 10 is grown such that an uppermost growth surface of ingot 10 (surface of ingot 10 in FIG. 7 opposite to a surface on which base substrate 1 is positioned, or surface of ingot 10 facing a direction indicated with an arrow 13 in FIG. 7 in which a source gas is supplied) grown on the surface of base substrate 1 is always flat (such that the surface of base substrate 1 and the uppermost growth surface of ingot 10 are parallel to each other). It is preferable that the main surface of base substrate 1 serving as a seed substrate (surface on which a crystal to become ingot 10 is grown) is tilted 1° or more and 10° or less in a <11-20> direction or a <1-100> direction relative to the (0001) plane. The tilt angle of the main surface may be set to 0.1° or more and 10° or less. By using such base substrate 1, (0001) facet 5 is generated only in a small area at the end portion of ingot 10 as shown in FIG. 7. While support member 2 shown in FIG. 3 is not illustrated and base substrate 1 is arranged directly on an inner wall of crucible 11 in the crystal growth device shown in FIG. 7, support member 2 may be arranged on base substrate 1 as shown in FIG. 3, and base substrate 1 may be fixed on the inner wall of crucible 11 with support member 2 interposed therebetween.

Here, making the uppermost growth surface of ingot 10 as flat as possible (e.g., causing the uppermost growth surface to extend in a direction perpendicular to the crystal growth direction) is a condition for generating a (0001) facet 5 as small as possible at the end portion of ingot 10. In order to make the flat uppermost growth surface, temperatures of a central portion 14, an end portion 15, and an outermost peripheral portion 16 on the uppermost growth surface of ingot 10 shown in FIG. 7 are important. End portion 15 is in an end portion area of ingot 10, and located at a distance of within 10% of a diameter of ingot 10 from the inner wall of crucible 11. When the temperature of central portion 14 is represented as Ta, the temperature of end portion 15 as Tb, and the temperature of outermost peripheral portion 16 as Tc, it is preferable that the relation among these temperatures satisfy a relational expression of Tc>Tb≧Ta, and that a temperature gradient between temperature Tb and temperature Ta ((absolute value of the difference between temperature Ta and temperature Tb)/(distance between central portion 14 and end portion 15)) be 10° C./cm or less.

In order to satisfy such temperature conditions, it is necessary to reduce temperature distribution (make temperature variation smaller) on a rear surface side of base substrate 1 (i.e., upper surface side of crucible 11 in FIG. 7). Specifically, it is preferable to employ a structure in which a heat dissipation hole formed on the upper surface side of crucible 11 has a diameter larger than the width of ingot 10, for example. Consequently, a radius of curvature between central portion 14 and end portion 15 on the surface of ingot 10 can be equal to or more than three times the radius of ingot 10. The radius of curvature is calculated as follows, for example. First, the height of ingot 10 (distance from the surface of base substrate 1 to the surface of ingot 10) is measured with a 5-mm pitch between central portion 14 and end portion 15. Then, from the difference in heights between the pitches, radii of arcs corresponding to the surface of ingot 10 between the pitches are calculated. Then, a minimum radius of the radii of the arcs calculated between the pitches between central portion 14 and end portion 15 is defined as the radius of curvature.

The flatness of the surface of ingot 10 may be measured with the following measurement method. That is, the height of the surface of ingot 10 from a reference surface is measured at a plurality of positions (measurement points) arranged in a crisscross direction with a 5-mm pitch (preferably in a matrix with a 5-mm pitch) from the center of the surface of ingot 10. Then, the difference in heights between adjacent measurement points is measured. Further, from a tangent (tan) determined from the difference in heights and the distance between the measurement points, an angle corresponding to the tilt of the surface of ingot 10 between the adjacent measurement points is determined. It is preferable that a plurality of angles thus determined be 10° or less on average. It is further preferable that all of measured angles be 10° or less. The measurement points are not arranged in a region at a distance of within 10% of the diameter of ingot 10 from the outermost peripheral portion of ingot 10.

As to the relation between temperature Tc and temperature Tb, it is preferable that an absolute value of the difference between temperature Tb and temperature Tc be 1° C. or more and 50° C. or less (more specifically, that temperature Tc be higher than temperature Tb, with the difference between temperature Tb and temperature Tc being 1° C. or more and 50° C. or less). If the absolute value of the difference is less than 1° C., a polycrystal of silicon carbide is likely to become attached to and grow on an inner peripheral surface of crucible 11 made of graphite, to prevent the growth of the single crystal ingot. If the difference is more than 50° C., the temperature of the end surface portion of ingot 10 also increases due to the effect of radiant heat and the like from crucible 11. The temperature difference between central portion 14 and end portion 15 thus increases, resulting in inability to maintain the flatness of the surface of ingot 10.

By growing the crystal under such conditions, the surface of ingot 10 becomes flat, and (0001) facet 5 is generated only at the end portion of ingot 10. It is preferable that a width of (0001) facet 5 (width of base substrate 1 in an off direction) be equal to or less than 10% of the diameter of ingot 10.

In order to arrange (0001) facet 5 at the end portion of ingot 10 as described above, it is preferable to have an environment without temperature distribution in a radial direction of ingot 10 (state where the temperature difference in the radial direction is small) throughout the process of growing ingot 10. For this purpose, the temperature needs to be carefully managed as follows during a temperature increasing step, and during a middle and late period of growth, respectively, aside from an initial period of growth.

For example, when a common high-frequency heating crucible is used for heating crucible 11, a side surface of crucible 11 is heated. Thus, in the temperature increasing step, temperature distribution tends to be generated in the radial direction of ingot 10. Accordingly, in the case where the temperature of a bottom surface of crucible 11 reaches 2000° C. or more from room temperature in one hour less, it is preferable to maintain the crucible under an atmospheric pressure of 40 kPa or more and 100 kPa or less and at a predetermined growth temperature for five minutes or more to make the temperature distribution uniform, and then reduce the atmospheric pressure to a predetermined growth pressure.

During the middle and late period of growth, ingot 10 is grown to a height of 1 cm or more, and thus the temperature of the uppermost growth surface becomes higher than during the initial period of growth. As a result, a temperature gradient between the uppermost growth surface of ingot 10 and the source becomes less steep. This causes a change in temperature environment at end portion 15 and outermost peripheral portion 16 from the state during the initial period of growth, which may include a reversal of magnitude relation between temperature Tb of end portion 15 and temperature Tc of outermost peripheral portion 16. Ingot 10 will have a concave shape in such state, causing (0001) facet 5 to move from the end portion toward the central portion of ingot 10.

During the middle and late period of growth, therefore, it is necessary to always maintain an environment satisfying the condition of temperature Tc>temperature Tb by making the temperature of the side surface of crucible 11 higher than that during the initial period of growth, or by increasing the amount of heat dissipated from the upper side of crucible 11. In addition, since the concave surface shape of ingot 10 increases the possibility of occurrence of a crack, it is preferable that ingot 10 have a flat or a slightly convex surface shape. It is further preferable to make an uppermost surface of the source for ingot 10 flat in advance, to prevent variation in filling depth of the source.

Ingot 10 according to the present invention formed with the method as described above has (0001) facet 5 of a small size, and a highly flat surface. Thus, the probability of occurrence of dislocations is substantially uniform across the surface of ingot 10, and uniformly decreases as ingot 10 grows. That is, in ingot 10 according to the present invention, dislocations can be reduced in substantially the entire region.

An alternative method of generating the facet only at the end portion of ingot 10 may be to make the temperature of the portion where the facet is to be generated higher than in the remaining portion. That is, it is preferable that a temperature Td of a facet-side end portion 17 and a temperature Te of a facet-side outermost peripheral portion 18 in FIG. 7 satisfy a relation of Te>Td, with the temperature difference between facet-side end portion 17 and facet-side outermost peripheral portion 18 (i.e., Te−Td) being 20° C. or more and 100° C. or less. Furthermore, since a large temperature difference between central portion 14 and end portion 15 increases the facet region, it is preferable to set a temperature gradient between central portion 14 and end portion 15 to 20° C./cm or less.

It is also preferable to create a relatively large temperature difference only between facet-side end portion 17 and facet-side outermost peripheral portion 18, while setting the temperature difference between end portion 15 and outermost peripheral portion 16 to 20° C. or less in the remaining portion of the outer circumferential portion of ingot 10. In order to achieve this, only a portion where facet 5 is to be formed may be heated, for example. If crucible 11 is heated with an induction heating method, for example, such heating can be conducted by shifting a center line of crucible 11 from a center line of coils 12 used for the heating toward the side where (0001) facet 5 is to be formed by a prescribed distance (e.g., about 1 mm or more and 5 mm or less). In addition, irrespective of a heating method, the thickness of a heat insulating material around crucible 11 may be increased only in a portion near the region where facet 5 is to be formed compared to the thickness of the remaining portion (may be increased by about 2 mm or more and about 10 cm or less from the thickness of the heat insulating material of the remaining portion). An alternative method may be to fill a hole formed for heat dissipation (heat dissipation hole) in the upper portion of crucible 11 in a region facing the portion where facet 5 is to be formed.

An alternative method of arranging facet 5 at the end portion of ingot 10 may be to arrange a temperature adjustment member 3 in support member 2 as shown in FIG. 3, and to vary a heating temperature of the region where facet 5 is to be formed (end portion of base substrate 1) compared to that of the remaining portion, for example. Such temperature adjustment member 3 may be implemented by a heating member such as an electric heater. An alternative method of arranging facet 5 at the end portion of ingot 10 may be to supply a source gas for growing silicon carbide on base substrate 1 only to the region where facet 5 is to be formed, or to make a growth rate of silicon carbide in the region where facet 5 is to be formed higher than in the remaining region by adjusting the arrangement of a discharge unit for discharging the source gas used for growing the silicon carbide from the inside of the processing container, for example.

Next, a post-processing step (S30) is performed. Specifically, ingot 10 thus formed is removed from the processing container, and necessary post-processing is performed such as grinding a surface layer, forming a mark on ingot 10 that indicates a crystal orientation of ingot 10, and further separating base substrate 1 from ingot 10.

Regarding an uppermost surface 9 (see FIG. 5) of a portion where the silicon carbide crystal has been grown in obtained ingot 10, it is preferable that a maximum radius of curvature in cross section shown in FIG. 5 be equal to or more than three times the radius of a circumscribed circle of the planar shape of ingot 10 shown in FIG. 4 (circle forming an outer circumference of the planar shape of ingot 10, if ingot 10 has a circular planar shape as shown in FIG. 4).

High concentration nitrogen region 6 is arranged on an upstream side in the off angle direction indicated with arrow 26. The off angle direction is a direction in which the off angle of base substrate 1 is set, and is either the <11-20> direction or the <1-100> direction, for example. When a <0001> direction axis of base substrate 1 intersects surface 4 of base substrate 1, a direction in which the <0001> direction axis is tilted relative to a normal of surface 4 is defined as the upstream side, and a direction opposite to the upstream side is defined as a downstream side. A nitrogen concentration in high concentration nitrogen region 6 is equal to or more than 1.1 times the nitrogen concentration in low concentration nitrogen region 7. The nitrogen concentration can be evaluated with SIMS, for example.

Moreover, a transmittance of light having a wavelength of 450 nm or more and 500 nm or less per unit thickness through high concentration nitrogen region 6 is lower than a transmittance of the same light per unit thickness through low concentration nitrogen region 7 other than high concentration nitrogen region 6 in ingot 10. The light transmittance can be measured with an FTIR (Fourier Transform Infrared Spectrometer), for example.

For example, the thickness of a substrate 20 can be set to 400 μm, and the transmittance of light having the above wavelength through high concentration nitrogen region 6 of substrate 20 in a thickness direction of substrate 20, and the transmittance of light having the above wavelength through low concentration nitrogen region 7 of substrate 20 in the thickness direction of substrate 20 can be measured with a visible light spectrometer.

According to such ingot 10, since high concentration nitrogen region 6 having a relatively high nitrogen concentration is arranged at the end portion of ingot 10, low concentration nitrogen region 7 having a relatively low nitrogen concentration can be formed as a large region including the central portion of ingot 10. Thus, when silicon carbide substrate 20 is cut from ingot 10, silicon carbide substrate 20 in which relatively low concentration nitrogen region 7 is formed in a large region including the substrate central portion can be readily obtained.

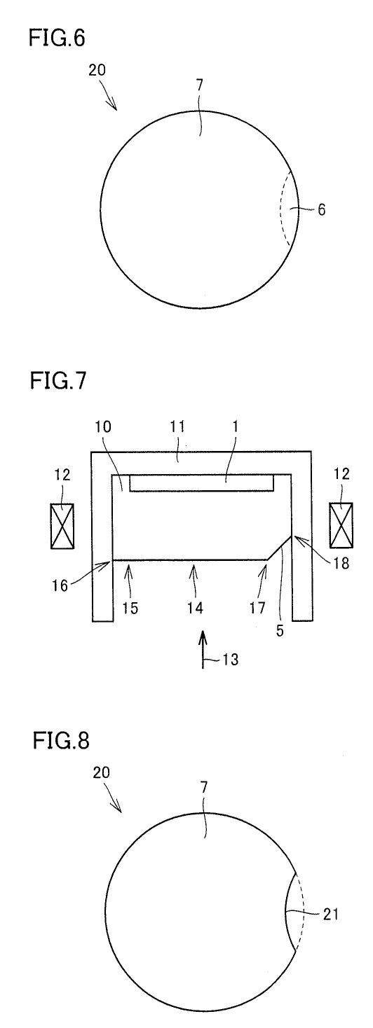

Next, ingot 10 thus obtained is used, to manufacture silicon carbide substrate 20 shown in FIG. 6 through a process shown in FIG. 2. Referring to FIG. 2, a method of manufacturing silicon carbide substrate 20 will be specifically described.

In the method of manufacturing a silicon carbide substrate according to the present invention, an ingot preparation step (S40) is initially performed as shown in FIG. 2. In this step (S40), ingot 10 made of silicon carbide and obtained by performing the steps shown in FIG. 1 is prepared.

Next, a slicing step (S50) is performed. Specifically, in the step (S50), ingot 10 is sliced in an arbitrary way. The slicing can be carried out with a wire saw, or with a cutting member having hard abrasive grains such as diamond arranged on a surface thereof (e.g., inner diameter blade), for example. Ingot 10 can be sliced in an arbitrary direction, such as a direction along surface 4 of base substrate 1 (direction along a straight line 8 in FIG. 5). In this case, high concentration nitrogen region 6 can be arranged at the end portion of silicon carbide substrate 20 that has been cut. Alternatively, ingot 10 may be sliced along a plane defined by the off angle direction of base substrate 1 and the normal of surface 4 of base substrate 1 (i.e., such that the cross section of ingot 10 shown in FIG. 5 will be a main surface of silicon carbide substrate 20).

Next, a post-processing step (S60) is performed. Specifically, a surface and/or a rear surface of the substrate obtained by the slicing is ground and polished to finish the surface into an arbitrary surface state such as a mirrored surface. Consequently, silicon carbide substrate 20 such as shown in FIG. 6 is obtained. In silicon carbide substrate 20, low concentration nitrogen region 7 is formed in a large portion including a central portion of the main surface, and high concentration nitrogen region 6 is arranged at the end portion. As shown in FIG. 8, high concentration nitrogen region 6 may be removed by grinding or the like, to form a recess 21 in an outer circumference of silicon carbide substrate 20. In this case, low concentration nitrogen region 7 is formed on substantially the entire surface of silicon carbide substrate 20, thereby obtaining silicon carbide substrate 20 having uniform characteristics.

According to such silicon carbide substrate 20, a silicon carbide epitaxial layer having highly uniform characteristics can be readily formed on the surface of silicon carbide substrate 20.

If the method of manufacturing a silicon carbide substrate shown in FIG. 2 is performed after high concentration nitrogen region 6 was removed from ingot 10 by grinding or the like in the post-processing step (S30) shown in FIG. 1, silicon carbide substrate 20 without the high concentration nitrogen region such as shown in FIG. 8, i.e., silicon carbide substrate 20 having the low concentration nitrogen region formed on the entire surface can be obtained. Silicon carbide substrate 20 shown in FIG. 8 basically has a structure similar to that of silicon carbide substrate 20 shown in FIG. 6, except that high concentration nitrogen region 6 shown in FIG. 6 has been removed. As a result, silicon carbide substrate 20 shown in FIG. 8 has recess 21 formed partially in the outer circumferential end portion where high concentration nitrogen region 6 was located. When this silicon carbide substrate 20 is obtained by slicing ingot 10 in the direction along straight line 8 in FIG. 5, recess 21 is positioned at the end portion in the off angle direction of silicon carbide substrate 20.

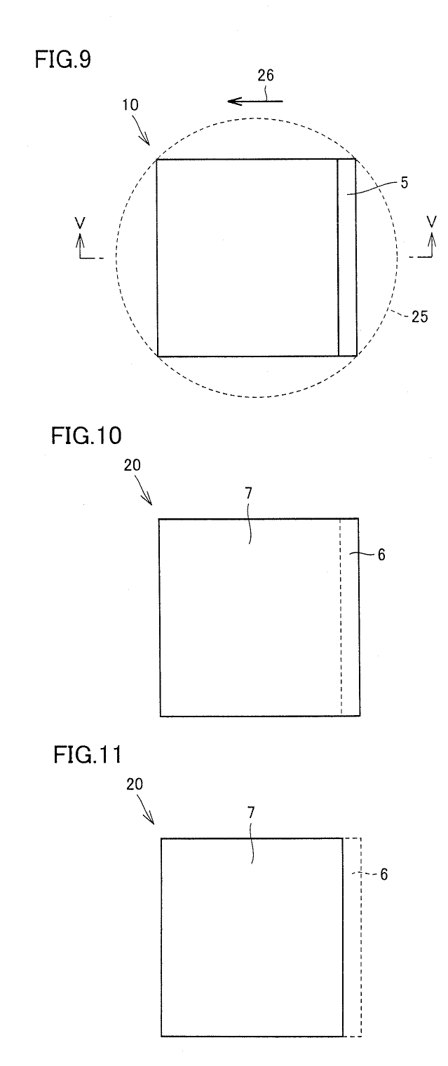

While a substrate having a circular planar shape is used as base substrate 1 in the methods for manufacturing ingot 10 and silicon carbide substrate 20 described above, a substrate having another arbitrary shape can be used as base substrate 1. If a substrate having a square planar shape is used as base substrate 1, for example, ingot 10 having a substantially square planar shape can be obtained as shown in FIG. 9. In this case too, facet 5 can be arranged at the end portion when ingot 10 is viewed two-dimensionally, by controlling the processing conditions in the film formation step (S20) shown in FIG. 1. A cross section along the line V-V in FIG. 9 is similar to that shown in FIG. 5. It is preferable that the maximum radius of curvature of the uppermost surface of obtained ingot 10 (maximum radius of curvature of uppermost surface 9 in FIG. 5) be equal to or more than three times the radius of a circumscribed circle 25 of the planar shape of ingot 10 shown in FIG. 9.

In this case too, by slicing ingot 10 in the direction parallel to surface 4 of base substrate 1 (i.e., direction indicated with straight line 8 in FIG. 5), silicon carbide substrate 20 having a planar shape such as shown in FIG. 10 can be obtained. In silicon carbide substrate 20 shown in FIG. 10 too, high concentration nitrogen region 6 is arranged at an end portion, and low concentration nitrogen region 7 is formed in the remaining region. This silicon carbide substrate 20 has an effect similar to that of silicon carbide substrate 20 shown in FIG. 6.

In addition, by removing high concentration nitrogen region 6 from silicon carbide substrate 20 shown in FIG. 10 by grinding or the like, silicon carbide substrate 20 having low concentration nitrogen region 7 formed on the entire surface thereof can be obtained as shown in FIG. 11. High concentration nitrogen region 6 may be removed from ingot 10 in advance in the step of forming ingot 10 (specifically, the post-processing step (S30) shown in FIG. 1). This silicon carbide substrate 20 has an effect similar to that of silicon carbide substrate 20 shown in FIG. 8.

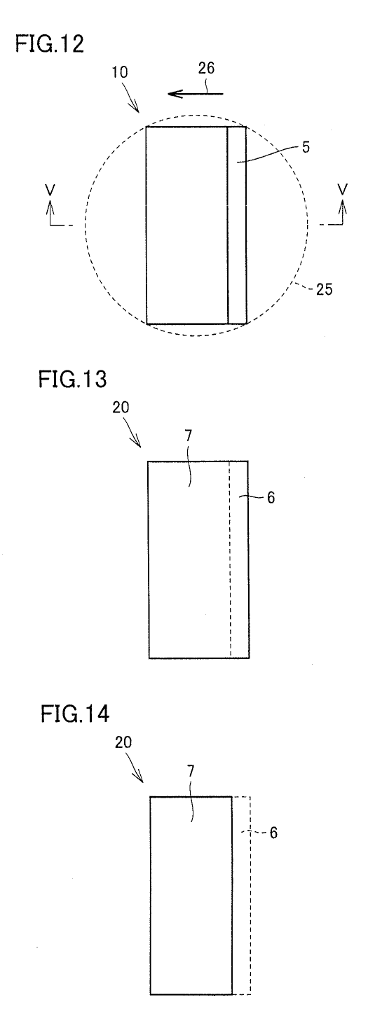

Alternatively, a substrate made of silicon carbide single crystal and having a rectangular planar shape such as shown in FIG. 12 can be used as base substrate 1 for forming ingot 10. In this case too, ingot 10 having the planar shape such as shown in FIG. 12 can be formed with the method of manufacturing an ingot shown in FIG. 1. A cross sectional shape along the line V-V of ingot 10 in FIG. 12 is basically similar to that of ingot 10 shown in FIG. 5. It is preferable that the maximum radius of curvature of uppermost surface 9 (see FIG. 5) of ingot 10 shown in FIG. 12 be equal to or more than three times the radius of circumscribed circle 25 of the planar shape of ingot 10 shown in FIG. 12.

Then, by slicing ingot 10 shown in FIG. 12 and subjecting ingot 10 to the post-processing with the method shown in FIG. 2, silicon carbide substrate 20 having a rectangular planar shape such as shown in FIG. 13 can be obtained. The slicing is carried out in a direction parallel to the plane of drawing of FIG. 12 (direction along the surface of the base substrate). In this silicon carbide substrate 20 too, high concentration nitrogen region 6 is formed at an end portion, and low concentration nitrogen region 7 is formed in the large remaining region. This silicon carbide substrate 20 has an effect similar to that of the substrate shown in FIG. 6.

Further, by removing high concentration nitrogen region 6 from silicon carbide substrate 20 shown in FIG. 13, silicon carbide substrate 20 having low concentration nitrogen region 7 formed on the entire surface thereof can be obtained as shown in FIG. 14. In this case, silicon carbide substrate 20 shown in FIG. 14 may be obtained by removing high concentration nitrogen region 6 from ingot 10 in the step of forming ingot 10 shown in FIG. 12, and slicing ingot 10 thereafter.

Alternatively, a substrate having a hexagonal planar shape can be used as base substrate 1. When such substrate is used as base substrate 1, ingot 10 having a hexagonal planar shape such as shown in FIG. 15 can be obtained. In this ingot 10 too, (0001) facet 5 can be arranged at the end portion of uppermost surface 9 (see FIG. 5) where the crystal of ingot 10 has been grown. A cross sectional view along the line V-V of ingot 10 shown in FIG. 15 is similar to that shown in FIG. 5. It is preferable that the maximum radius of curvature of uppermost surface 9 of obtained ingot 10 (maximum radius of curvature of uppermost surface 9 in FIG. 5) be equal to or more than three times the radius of circumscribed circle 25 of the planar shape of ingot 10 shown in FIG. 15.

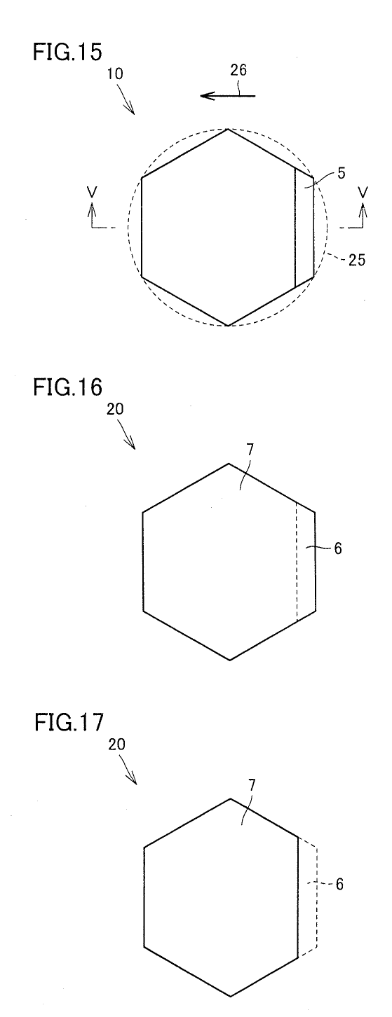

Then, by slicing and processing ingot 10 shown in FIG. 15 with the method shown in FIG. 2, silicon carbide substrate 20 having a hexagonal planar shape such as shown in FIG. 16 can be obtained. The slicing is carried out in a direction parallel to the plane of drawing of FIG. 15 (direction along the surface of base substrate 1). In this silicon carbide substrate 20 too, high concentration nitrogen region 6 is arranged at an end portion, and low concentration nitrogen region 7 is formed in the remaining region. This substrate has an effect similar to that of the substrate shown in FIG. 6.

Further, by removing high concentration nitrogen region 6 from silicon carbide substrate 20 shown in FIG. 16 by grinding or the like, silicon carbide substrate 20 having low concentration nitrogen region 7 formed on the entire surface thereof can be obtained as shown in FIG. 17. In this case, silicon carbide substrate 20 shown in FIG. 17 may be obtained by removing high concentration nitrogen region 6 from ingot 10 in the step of forming ingot 10 shown in FIG. 15, and slicing ingot 10 thereafter.

While some of them have already been discussed in the above embodiment, the characteristic features of the present invention will now be described.

As shown in FIG. 1, the method of manufacturing silicon carbide ingot 10 according to the present invention includes the steps of preparing base substrate 1 made of single crystal silicon carbide and having an off angle of 0.1° or more and 10° or less, more preferably 1° or more and 10° or less, in an off angle direction which is either a <11-20> direction or a <1-100> direction relative to a (0001) plane (preparation step (S10)), and growing a silicon carbide layer on a surface of base substrate 1 (film formation step (S20)). In the film formation step (S20), a region having (0001) facet 5 is formed on a surface of the grown silicon carbide layer at an end portion on an upstream side, the upstream side being a side where an angle of intersection between a <0001> direction axis of base substrate 1 and surface 4 of base substrate 1 in the off angle direction is an acute angle.

By forming (0001) facet 5 into which nitrogen is readily taken at the end portion of ingot 10 in this manner, a region having a relatively high nitrogen concentration (high concentration nitrogen region 6 located below the (0001) facet) can be arranged at the end portion of silicon carbide ingot 10. Thus, a region having a relatively low nitrogen concentration (low concentration nitrogen region 7 other than the high concentration nitrogen region) can be formed as a large region including the central portion of silicon carbide ingot 10. Accordingly, when silicon carbide substrate 20 is cut from ingot 10, silicon carbide substrate 20 in which low concentration nitrogen region 7 is formed in a large region including the substrate central portion can be readily obtained. Since low concentration nitrogen region 7 (i.e., region having a stable nitrogen concentration with little nitrogen taken therein) can be formed in a large region including the substrate central portion in this manner, a semiconductor device can be efficiently formed on the surface of silicon carbide substrate 20 with improved utilization efficiency of the substrate.

In the method of manufacturing a silicon carbide ingot described above, in the silicon carbide layer after the step of growing a silicon carbide layer (film formation step (S20)), a portion located below the region having the (0001) facet may be high concentration nitrogen region 6 having a nitrogen concentration higher than in a portion (low concentration nitrogen region 7) other than the portion located below the region having the (0001) facet in the silicon carbide layer.

In this case, high concentration nitrogen region 6 is formed below the region having (0001) facet 5, and low concentration nitrogen region 7 having a nitrogen concentration lower than in high concentration nitrogen region 6 is formed in the remaining portion including the ingot central portion. Accordingly, silicon carbide substrate 20 having low concentration nitrogen region 7 formed in a large region including the surface central portion can be readily obtained by slicing this silicon carbide ingot 10.

In the method of manufacturing a silicon carbide ingot described above, a width of high concentration nitrogen region 6 in the off angle direction (direction along arrow 26 in FIG. 3) may be equal to or less than 1/10 of a width of base substrate 1 in the off angle direction. In this case, the size of high concentration nitrogen region 6 is sufficiently small relative to the entire silicon carbide ingot 10. Thus, the area occupied by high concentration nitrogen region 6 can be reduced on the surface (main surface) of silicon carbide substrate 20 obtained from silicon carbide ingot 10. Consequently, low concentration nitrogen region 7 (having a stable nitrogen concentration) of a sufficiently large size can be formed on the surface of silicon carbide substrate 20. Moreover, high concentration nitrogen region 6 can be readily removed in the step of grinding and shaping the outer circumference of silicon carbide ingot 10, thereby suppressing an increase in time required for processing silicon carbide ingot 10.

The method of manufacturing a silicon carbide ingot described above may further include the step of removing the high concentration nitrogen region (post-processing step (S30) in FIG. 1). In this case, low concentration nitrogen region 7 can be formed in a large portion of silicon carbide ingot 10. As a result, low concentration nitrogen region 7 can be formed on the entire surface of silicon carbide substrate 20 cut from silicon carbide ingot 10, thereby obtaining silicon carbide substrate 20 having a stable nitrogen concentration and high uniformity.

In the method of manufacturing a silicon carbide ingot described above, a transmittance of light having a wavelength of 450 nm or more and 500 nm or less per unit thickness through high concentration nitrogen region 6 may be lower than a transmittance of the same light per unit thickness through the portion (low concentration nitrogen region 7) other than the high concentration nitrogen region in the silicon carbide layer (silicon carbide layer grown on base substrate 1).

The above light transmittance through silicon carbide ingot 10 tends to decrease as the nitrogen concentration increases. Thus, high concentration nitrogen region 6 and the region (low concentration nitrogen region 7) other than the high concentration nitrogen region have different values with regard to the light transmittance characteristic as well. According to the present invention, therefore, since the region having a relatively low light transmittance (high concentration nitrogen region 6) is arranged at the end portion of silicon carbide ingot 10, the region having a relatively high light transmittance (low concentration nitrogen region 7) can be formed as a large region including the central portion of silicon carbide ingot 10, with regard to the light transmittance characteristic as well. Thus, when silicon carbide substrate 20 is cut from silicon carbide ingot 10, silicon carbide substrate 20 in which the region having a relatively high light transmittance is formed in a large region including the substrate central portion can be readily obtained.

In the method of manufacturing silicon carbide ingot 10 described above, a micropipe density of the portion (high concentration nitrogen region 6) located below the region having the (0001) facet may be higher than a micropipe density of the portion (low concentration nitrogen region 7) other than the portion located below the region having the (0001) facet in the silicon carbide layer. In this case, since high concentration nitrogen region 6 having a relatively high micropipe density is arranged at the end portion of silicon carbide ingot 10, the region having a relatively low micropipe density (low concentration nitrogen region 7) can be formed as a large region including the central portion of silicon carbide ingot 10, with regard to the micropipe density characteristic as well. Thus, when silicon carbide substrate 20 is cut from silicon carbide ingot 10, silicon carbide substrate 20 in which the region having a relatively low micropipe density (low concentration nitrogen region 7) is formed in a large region including the substrate central portion can be readily obtained.

In the method of manufacturing silicon carbide ingot 10 described above, the maximum radius of curvature of the surface (uppermost surface 9 shown in FIG. 5) of the silicon carbide layer after the step of growing a silicon carbide layer (film formation step (S20)) may be equal to or more than three times the radius of circumscribed circle 25 of the planar shape of base substrate 1. It is preferable that the maximum radius of curvature of the surface (uppermost surface 9 in FIG. 5) of the silicon carbide layer be the maximum radius of curvature of a region (uppermost surface) including a portion farthest away from the surface of base substrate 1 in the silicon carbide layer.

In this case, the silicon carbide layer formed on base substrate 1 can have a sufficiently large volume, thereby ensuring a sufficiently large volume of silicon carbide ingot 10. Thus, when silicon carbide substrate 20 is cut from silicon carbide ingot 10, silicon carbide substrate 20 having a large area can be efficiently obtained. The silicon carbide layer (silicon carbide epitaxial growth layer including high concentration nitrogen region 6 and low concentration nitrogen region 7) may be formed with a planar shape larger than the planar shape of base substrate 1 (e.g., such that the planer shape becomes larger with an increase in distance from base substrate 1, or with a sidewall tilted outward with an increase in distance from base substrate 1).

Silicon carbide ingot 10 according to the present invention is manufactured with the method of manufacturing silicon carbide ingot 10 described above. In this case, the region having a relatively low nitrogen concentration (low concentration nitrogen region 7) can be formed as a large region including the central portion of silicon carbide ingot 10. Thus, when silicon carbide substrate 20 is cut from silicon carbide ingot 10, silicon carbide substrate 20 in which low concentration nitrogen region 7 having a relatively low nitrogen concentration is formed in a large region including the substrate central portion can be readily obtained.

As shown in FIG. 2, the method of manufacturing silicon carbide substrate 20 according to the present invention includes the steps of preparing a silicon carbide ingot (ingot preparation step (S40)) using the method of manufacturing silicon carbide ingot 10 described above, and slicing silicon carbide ingot 10 (slicing step (S50)).

In this case, in silicon carbide ingot 10, the region having a relatively low nitrogen concentration (low concentration nitrogen region 7 other than the high concentration nitrogen region) is formed as a large region including the central portion of silicon carbide ingot 10. Thus, when silicon carbide substrate 20 is cut from silicon carbide ingot 10 in the slicing step (S50), silicon carbide substrate 20 in which low concentration nitrogen region 7 having a relatively low nitrogen concentration is formed in a large region including the substrate central portion can be readily obtained.

In the step of preparing a silicon carbide ingot (ingot preparation step (S40)) in the method of manufacturing a silicon carbide substrate described above, in the silicon carbide layer after the step of growing a silicon carbide layer (film formation step (S20)), a portion located below the region having the (0001) facet may be high concentration nitrogen region 6 having a nitrogen concentration higher than in a portion (low concentration nitrogen region 7) other than the portion located below the region having the (0001) facet in the silicon carbide layer. The method of manufacturing a silicon carbide substrate described above may further include, before the slicing step (S50) of slicing silicon carbide ingot 10, the step of removing high concentration nitrogen region 6 from silicon carbide ingot 10 (e.g., step of removing high concentration nitrogen region 6 included in the post-processing step (S30) in FIG. 1 by grinding).

From a different point of view, as shown in FIG. 2, the method of manufacturing silicon carbide substrate 20 according to the present invention includes the step of preparing a silicon carbide ingot (ingot preparation step (S40)) using the method of manufacturing silicon carbide ingot 10 described above. In the step of preparing a silicon carbide ingot (ingot preparation step (S40)), in the silicon carbide layer after the step of growing a silicon carbide layer (film formation step (S20)), a portion located below the region having the (0001) facet may be high concentration nitrogen region 6 having a nitrogen concentration higher than in a portion (low concentration nitrogen region 7) other than the portion located below the region having the (0001) facet in the silicon carbide layer. The method further includes the steps of removing high concentration nitrogen region 6 from silicon carbide ingot 10 (e.g., step of removing high concentration nitrogen region 6 included in the post-processing step (S30) in FIG. 1 by grinding), and slicing silicon carbide ingot 10 (slicing step (S50)) after performing the step of removing high concentration nitrogen region 6.

In this case, high concentration nitrogen region 6 is removed from silicon carbide ingot 10 from which silicon carbide substrate 20 is cut, thereby improving the uniformity in nitrogen concentration, transmittance and the like in silicon carbide ingot 10.

Silicon carbide substrate 20 according to the present invention is manufactured with the method of manufacturing a silicon carbide substrate described above. Consequently, silicon carbide substrate 20 in which low concentration nitrogen region 7 having a relatively low nitrogen concentration is formed in a large region including the substrate central portion can be readily realized.

The method of manufacturing a silicon carbide ingot according to the present invention includes the steps of preparing base substrate 1 made of single crystal silicon carbide and having an off angle of 0.1° or more and 10° or less, more preferably 1° or more and 10° or less, in an off angle direction (direction indicated with arrow 26 in FIG. 3) which is either a <11-20> direction or a <1-100> direction relative to a (0001) plane (preparation step (S10)), and growing a silicon carbide layer on a surface of base substrate 1 (film formation step (S20)). In the film formation step (S20), a region having (0001) facet 5 is formed on a surface of the grown silicon carbide layer at an end portion on an upstream side, the upstream side being a side where an angle of intersection between a <0001> direction axis of base substrate 1 and surface 4 of base substrate 1 in the off angle direction is an acute angle. In the silicon carbide layer after the film formation step (S20), a transmittance of light having a wavelength of 450 nm or more and 500 nm or less per unit thickness through a portion (high concentration nitrogen region 6) located below the region having (0001) facet 5 is lower than a transmittance of the same light per unit thickness through a portion (low concentration nitrogen region 7) other than the portion located below the region having (0001) facet 5 in the silicon carbide layer.

By forming (0001) facet 5 into which nitrogen is readily taken at the end portion of silicon carbide ingot 10 in this manner, a region having a reduced light transmittance due to the nitrogen taken therein from (0001) facet 5 during the growth of the silicon carbide layer (high concentration nitrogen region 6) is arranged at the end portion of silicon carbide ingot 10 (portion below (0001) facet 5). Thus, the remaining region (low concentration nitrogen region 7) including the central portion of silicon carbide ingot 10 can be formed as a region having a relatively high light transmittance. Accordingly, when silicon carbide substrate 20 is cut from silicon carbide ingot 10, silicon carbide substrate 20 in which the region having a relatively increased light transmittance (low concentration nitrogen region 7) is formed in a large region including the substrate central portion can be readily obtained. Since the region having a relatively high light transmittance (region having stable nitrogen concentration and transmittance with little nitrogen taken therein) can be formed in a large region including the substrate central portion in this manner, a semiconductor device can be efficiently formed on the surface of the substrate.

Silicon carbide ingot 10 according to the present invention includes base substrate 1 made of single crystal silicon carbide and having an off angle of 0.1° or more and 10° or less, more preferably 1° or more and 10° or less, in an off angle direction which is either a <11-20> direction or a <1-100> direction relative to a (0001) plane, and a silicon carbide layer formed on a surface of base substrate 1. A region having (0001) facet 5 is formed on a surface of the grown silicon carbide layer at an end portion on an upstream side, the upstream side being a side where an angle of intersection between a <0001> direction axis of the base substrate and surface 4 of base substrate 1 in the off angle direction is an acute angle.

In the silicon carbide layer of silicon carbide ingot 10, a portion located below the region having (0001) facet 5 may be high concentration nitrogen region 6 having a nitrogen concentration higher than in a portion (low concentration nitrogen region 7) other than the portion located below the region having the (0001) facet in the silicon carbide layer.

By forming (0001) facet 5 into which nitrogen is readily taken at the end portion of ingot 10 in this manner, the region having a relatively high nitrogen concentration (high concentration nitrogen region 6 located below (0001) facet 5) can be arranged at the end portion of silicon carbide ingot 10. Thus, the region having a relatively low nitrogen concentration (low concentration nitrogen region 7) can be formed as a large region including the central portion of silicon carbide ingot 10. Accordingly, when silicon carbide substrate 20 is cut from ingot 10, silicon carbide substrate 20 in which low concentration nitrogen region 7 is formed in a large region including the substrate central portion can be readily obtained.

In silicon carbide ingot 10, a nitrogen concentration in high concentration nitrogen region 6 may be equal to or more than 1.1 times the nitrogen concentration in the portion (low concentration nitrogen region 7) other than the portion located below the region having (0001) facet 5.

In this case, high concentration nitrogen region 6 and low concentration nitrogen region 7 can be readily distinguished from each other by the nitrogen concentration, light transmittance and the like. Accordingly, when removing high concentration nitrogen region 6 from silicon carbide ingot 10 by grinding, or when cutting silicon carbide substrate 20 from silicon carbide ingot 10 to form a device on a surface of silicon carbide substrate 20, the device can be readily formed in a region other than high concentration nitrogen region 6 (or can be formed not over a boundary portion between high concentration nitrogen region 6 and low concentration nitrogen region 7).

In silicon carbide ingot 10, a width of high concentration nitrogen region 6 in the off angle direction may be equal to or less than 1/10 of a width of base substrate 1 in the off angle direction. In this case, the size of high concentration nitrogen region 6 is small, thereby ensuring a sufficiently large size of the region (low concentration nitrogen region 7) other than high concentration nitrogen region 6.

In silicon carbide ingot 10, a transmittance of light having a wavelength of 450 nm or more and 500 nm or less per unit thickness through high concentration nitrogen region 6 may be lower than a transmittance of the same light per unit thickness through the portion (low concentration nitrogen region 7) other than the high concentration nitrogen region in the silicon carbide layer.

In this case, high concentration nitrogen region 6 and low concentration nitrogen region 7 can be readily distinguished from each other by the light transmittance. Accordingly, high concentration nitrogen region 6 can be readily removed from silicon carbide ingot 10 by grinding.

In silicon carbide ingot 10, the transmittance through high concentration nitrogen region 6 may be lower by 5% or more than the transmittance through low concentration nitrogen region 7 other than the high concentration nitrogen region in the silicon carbide layer. In this case, high concentration nitrogen region 6 and low concentration nitrogen region 7 can be readily distinguished from each other by the transmittance difference.

In silicon carbide ingot 10, a micropipe density of the portion (high concentration nitrogen region 6) located below the region having the (0001) facet may be higher than a micropipe density of the portion (low concentration nitrogen region 7) other than the portion located below the region having (0001) facet 5 in the silicon carbide layer. In this case, the portion (low concentration nitrogen region 7 having a relatively low micropipe density) other than the portion located below the region having (0001) facet 5 is formed as a large region including the central portion of silicon carbide ingot 10. Thus, when silicon carbide substrate 20 is cut from ingot 10, silicon carbide substrate 20 in which the region having a relatively low micropipe density is foamed in a large region including the substrate central portion can be readily obtained.

In silicon carbide ingot 10, the micropipe density of the portion (high concentration nitrogen region 6) located below the region having (0001) facet 5 may be equal to or more than 1.2 times the micropipe density of the portion (low concentration nitrogen region 7) other than the portion located below the region having (0001) facet 5 in the silicon carbide layer.

In this case, low concentration nitrogen region 7 other than the portion located below the region having (0001) facet 5 consequently has a relatively low micropipe density. Thus, silicon carbide ingot 10 having a reduced micropipe density in the large region including the central portion can be obtained.

In silicon carbide ingot 10, the maximum radius of curvature of the surface (uppermost surface 9 shown in FIG. 5) of the silicon carbide layer may be equal to or more than three times the radius of circumscribed circle 25 of the planar shape of base substrate 1. In this case, the silicon carbide layer formed on base substrate 1 can have a sufficiently large volume, thereby ensuring a sufficiently large volume of silicon carbide ingot 10.

Silicon carbide substrate 20 according to the present invention is obtained by slicing silicon carbide ingot 10. Consequently, silicon carbide substrate 20 in which low concentration nitrogen region 7 having a relatively low nitrogen concentration (or region having a high light transmittance) is formed in a large region including the substrate central portion can be readily obtained.

Silicon carbide substrate 20 according to the present invention may be obtained by slicing silicon carbide ingot 10, after removing high concentration nitrogen region 6 from silicon carbide ingot 10. Consequently, since high concentration nitrogen region 6 (region having a low light transmittance) is removed in advance, silicon carbide substrate 20 is formed using silicon carbide ingot 10 in which low concentration nitrogen region 7 having a nitrogen concentration lower than in high concentration nitrogen region 6 (region having a light transmittance higher than in the high concentration nitrogen region) is formed in a large region thereof (or in which only low concentration nitrogen region 7 is formed). Accordingly, silicon carbide substrate 20 with smaller variation in nitrogen concentration and light transmittance can be obtained.

In silicon carbide substrate 20, the nitrogen concentration may vary from an average value by equal to or less than 10%. In this case, the variation in nitrogen concentration is sufficiently small so as not to adversely affect the characteristics of silicon carbide substrate 20, thereby ensuring silicon carbide substrate 20 having uniform characteristics.

In silicon carbide substrate 20, the dislocation density may vary from an average value by equal to or less than 80%. Further, the dislocation density in low concentration nitrogen region 7 may vary from an average value by equal to or less than 80%. With such variations in dislocation density, characteristic change in the main surface of silicon carbide substrate 20 can be suppressed so as not to present practical problems.

In silicon carbide substrate 20 according to the present invention, high concentration nitrogen region 6 having a nitrogen concentration relatively higher than in the remaining portion is formed at one end portion in either the <11-20> direction or the <1-100> direction. High concentration nitrogen region 6 may be formed at the end portion on the upstream side, the upstream side being a side where an angle of intersection between the <0001> direction axis of silicon carbide substrate 20 and the surface of silicon carbide substrate 20 in either the <11-20> direction or the <1-100> direction (off angle direction) is an acute angle. Consequently, when growing silicon carbide ingot 10 used for forming silicon carbide substrate 20, high concentration nitrogen region 6 can be readily arranged at an end portion of silicon carbide substrate 20 by controlling the arrangement of (0001) facet 5.

Silicon carbide substrate 20 may have a size (e.g., maximum width when viewed two-dimensionally) of 4 inches or more. The present invention can have a noticeable effect particularly in terms of manufacturing efficiency of a device when applied to silicon carbide substrate 20 having a size of 4 inches or more.

In silicon carbide substrate 20, a nitrogen concentration in high concentration nitrogen region 6 may be equal to or more than 1.1 times the nitrogen concentration in the remaining portion. In this case, high concentration nitrogen region 6 and the portion (low concentration nitrogen region 7) other than the high concentration nitrogen region can be readily distinguished from each other by the light transmittance or the like.

In silicon carbide substrate 20, the width of high concentration nitrogen region 6 in either the <11-20> direction or the <1-100> direction may be equal to or less than 1/10 of the width of silicon carbide substrate 20 in the same direction. In this case, the size of high concentration nitrogen region 6 is small, thereby ensuring a sufficiently large size of the region (low concentration nitrogen region 7) other than high concentration nitrogen region 6.

In silicon carbide substrate 20, a transmittance of light having a wavelength of 450 nm or more and 500 nm or less per unit thickness through high concentration nitrogen region 6 may be lower than a transmittance of light having a wavelength of 450 nm or more and 500 nm or less light per unit thickness through the portion (low concentration nitrogen region 7) other than the high concentration nitrogen region. Further, the transmittance through high concentration nitrogen region 6 may be lower than the transmittance through the portion (low concentration nitrogen region 7) other than the high concentration nitrogen region by 5% or more.

In this case, high concentration nitrogen region 6 and low concentration nitrogen region 7 can be readily distinguished from each other by the light transmittance. Accordingly, when forming a device on the surface of silicon carbide substrate 20, the device can be readily formed in a region other than high concentration nitrogen region 6 (or can be formed not over a boundary portion between high concentration nitrogen region 6 and the remaining region).

In silicon carbide substrate 20, a micropipe density of high concentration nitrogen region 6 may be higher than a micropipe density of the portion (low concentration nitrogen region 7) other than the high concentration nitrogen region. Further, in silicon carbide substrate 20, the micropipe density of high concentration nitrogen region 6 may be equal to or more than 1.2 times the micropipe density of the portion (low concentration nitrogen region 7) other than the high concentration nitrogen region.

In this case, the micropipe density is reduced in low concentration nitrogen region 7 occupying a large portion of the silicon carbide substrate. Thus, when forming a silicon carbide epitaxial layer on the surface of silicon carbide substrate 20, the occurrence of detects resulting from micropipes in silicon carbide substrate 20 can be suppressed in the silicon carbide epitaxial layer.

In the silicon carbide substrate, the nitrogen concentration may vary from an average value by equal to or less than 10%. In this case, the variation in nitrogen concentration is sufficiently small so as not to adversely affect the characteristics of the silicon carbide substrate, thereby ensuring the silicon carbide substrate having uniform characteristics.

In the silicon carbide substrate, the dislocation density may vary from an average value by equal to or less than 80%. Further, the dislocation density in the low concentration nitrogen region may vary from an average value by equal to or less than 80%. With such variations in dislocation density, characteristic change in the main surface of the silicon carbide substrate can be suppressed so as not to present practical problems.

As described above, according to the method of manufacturing a silicon carbide ingot of the present invention, the facet can be arranged at an end portion of silicon carbide ingot 10. In this case, by grinding only the end portion of ingot 10 and then slicing ingot 10, substrate 20 without a facet on the entire surface can be obtained. The facet and the region other than the facet are different from each other in the amount of doped nitrogen, and main dislocation. While substrate 20 having a size of less than 4 inches is not greatly influenced by the difference, the substrate having a size of 4 inches or more is significantly influenced, making the effect of the present invention particularly noticeable.

When substrate 20 is subjected to a polishing step, the amount of nitrogen doped into the silicon carbide substrate has an influence on a CMP polishing rate. It is thus preferable that the amount of nitrogen doped into substrate 20 be uniform. When the substrate has a size of 4 inches or more, warp and TTV of substrate 20 also increase with the increased substrate size. The effect of the amount of doped nitrogen also becomes noticeable. That is, when in-plane variation in the amount of doped nitrogen into the substrate becomes smaller, variation in internal stress distribution due to an impurity such as nitrogen becomes smaller, to improve the warp and TTV.

Further, the step of forming a device (e.g., heat treatment step) is also influenced by the amount of doped nitrogen and the like. That is, different amounts of doped nitrogen change a light absorptivity of the substrate, causing a local temperature difference when the substrate is heated. Substrate 20 having a small size is not significantly influenced by this temperature difference because of the effect of thermal conduction. When the substrate has a large diameter of 4 inches or more, however, the effect of thermal conduction becomes smaller as the temperature increases, and thus temperature distribution is likely to occur in substrate 20. Consequently, the temperature conditions vary in the plane of the substrate, resulting in failure to form a uniform film on the substrate surface. The occurrence of such problem can be suppressed in the substrate obtained from ingot 10 according to the present invention, because of the highly uniform amount of doped nitrogen.

The amount of doped nitrogen (nitrogen concentration) can be measured with SIMS. In ingot 10 made of silicon carbide according to the present invention, for example, the nitrogen concentration in a portion with a high amount of doped nitrogen is equal to or more than 1.5 times the nitrogen concentration in the remaining region.

If substrate 20 cut from ingot 10 according to the present invention has a thickness of 400 μm, it is preferable that a transmittance of light having a wavelength of 400 nm or more and 500 nm or less through substrate 20 satisfy the following conditions. That is, when the light transmittance is measured at a plurality of portions (e.g., 10 portions including a central portion) of substrate 20 with a visible light spectrometer, it is preferable that an average light transmittance be 20% or more and 65% or less. It is also preferable that, in a large portion of the main surface of the substrate (region of equal to or more than 70% in area ratio), a local transmittance be within ±20% of the average transmittance. It is also preferable that substrate 20 have a refractive index of 2.5 or more and 2.8 or less.

The dislocation density of the substrate was measured by processing the substrate surface by etching with molten salt KOH as an etching solution to visualize dislocations. Specifically, the molten salt KOH was heated to 500° C., and substrate 20 was immersed in the solution of molten salt KOH for about 1 to 10 minutes. As a result, pits corresponding to the dislocations were formed in the surface of substrate 20. Then, the number of pits was counted with a Nomarski differential interference microscope and divided by the area of measurement range, to calculate the number of pits per unit area (i.e., the number of dislocations per unit area).

If the number of dislocations is measured for substrate 20 obtained by slicing ingot 10 according to the present invention in a position at a distance of 20 mm from base substrate 1, with a micropipe density (MPD) of 10 to 100 cm⁻² and an etch pit density (EPD) of 1 to 5 E4 cm⁻² as dislocation densities of base substrate 1, the micropipe density and the etch pit density decrease to between about ½ and about 1/20 relative to those of base substrate 1.

### Examples

To confirm the effects of the present invention, ingots and substrates were manufactured and their characteristics were measured as follows.

(Samples)

Samples of a silicon carbide ingot and a silicon carbide substrate obtained by slicing the silicon carbide ingot were prepared as follows in an example and a comparative example of the present invention.

<Sampling Base Substrates in Example and Comparative Example of Present Invention>

In order to manufacture silicon carbide ingots, silicon carbide single crystal substrates having the following conditions were prepared as base substrates. Specifically, in order to manufacture the ingot according to the present invention, six 4H-SiC single crystal substrates (three for the example and three for the comparative example) were prepared as base substrates 1. Base substrates 1 had a diameter of 50 to 180 mm, and a thickness of 100 to 2000 μm. Base substrates 1 had a thickness of 800 μm. Main surfaces of base substrates 1 had an off angle of 4° in the <11-20> direction relative to the (0001) plane. At least a surface of each base substrate 1 on which a crystal was to be grown was subjected to mirror polishing. Base substrates 1 had a micropipe density (MPD) of 10 to 100 cm⁻² and an etch pit density (EPD) of 1 to 5 E4 cm⁻² as dislocation densities. These dislocation densities were measured as follows. That is, after each base substrate 1 was immersed for 1 to 10 minutes in KOH molten by being heated to 500° C., the number of pits was counted by observation of the surface of the base substrate with a Nomarski differential interference microscope. Then, the number of pits per unit area was calculated from the area of the observed region and the counted number.

(Experimental Method)

Manufacture of Ingots:

<Ingots in Example>

A silicon carbide ingot in the example was manufactured by forming a silicon carbide epitaxial layer on a surface of each of the base substrates in the example. Specifically, base substrate 1 and SiC in the form of powder which is a source of base substrate 1 were introduced into a crucible made of graphite. A distance between the source and the base substrate was set within a range from 10 mm to 100 mm. A common growth method such as a sublimation method or an improved Rayleigh method was used for the manufacture. Specifically, this crucible was disposed in a heating crucible and raised in temperature. During the temperature rise, an atmospheric pressure was set within a range from 50 kPa to atmospheric pressure. During crystal growth, a temperature of a lower portion of the crucible was set within a range from 2200° C. or more to 2500° C. or less, and a temperature of an upper portion of the crucible was set within a range from 2000° C. or more to 2350° C. or less. The temperature of the lower portion of the crucible was set higher than that of the upper portion of the crucible. The atmospheric pressure was controlled within a range from 0.1 to 20 kPa after the temperature was raised for the crystal growth. Any one of He, Ar, N₂, or a mixed gas including two or more of He, Ar, N₂ were used as an atmospheric gas. An Ar+N₂ gas was used as the atmospheric gas in this case. During cooling, the atmospheric pressure was increased to the range from 50 kPa to atmospheric pressure, before the temperature of the heating crucible was lowered.

During the crystal growth, ingot 10 was grown such that an uppermost growth surface of ingot 10 (surface of ingot 10 in FIG. 7 opposite to a surface on which base substrate 1 is positioned, or surface of ingot 10 facing a direction indicated with arrow 13 in FIG. 7 in which a source gas is supplied) grown on the surface of base substrate 1 was always flat as shown in FIG. 7. Specifically, as described with reference to FIG. 7, when the temperature of central portion 14 of ingot 10 in FIG. 7 is represented as Ta, the temperature of end portion 15 as Tb, and the temperature of outermost peripheral portion 16 as Tc, the crystal was grown such that the relation among these temperatures satisfied the relational expression of Tc>Tb≧Ta, and that the temperature gradient between temperature Tb and temperature Ta ((absolute value of the difference between temperature Ta and temperature Tb)/(distance between central portion 14 and end portion 15)) was 10° C./cm or less. Specifically, the diameter of a heat dissipation hole in a felt positioned at an upper surface side of the crucible was made larger than the diameter of ingot 10. The ingot made of silicon carbide grown on the base substrate in this manner was removed.

<Ingots in Comparative Example>

A silicon carbide ingot in the comparative example was manufactured by forming a silicon carbide epitaxial layer on a surface of each of the base substrates in the comparative example. The ingot in the comparative example was basically manufactured in a manner similar to that for manufacturing the ingot in the example described above, except that a felt was arranged directly on the upper surface of the crucible, with a heat dissipation hole having a diameter of 20 mm formed in a central portion of the felt. Consequently, a heat dissipation effect was greater only near the heat dissipation hole, resulting in a temperature gradient of 10° C./cm or more between central portion 14 and end portion 15 of the formed ingot. The ingot made of silicon carbide grown in this manner in the comparative example was removed.

Measurement of Flatness of Uppermost Surfaces of Ingots:

The flatness of the surfaces was measured for the ingots in the example and the comparative example. The flatness of each ingot was determined by measuring the height of the ingot (distance from the surface of the base substrate to the surface of the ingot) in a (central) region other than an area within a range of 10% relative to the diameter of the ingot on the outer circumferential side. While it is preferable to have height distribution across the surface of the ingot, it is only required to measure the height of the ingot with a 1- to 5-mm pitch in a crisscross direction from the center of the ingot.

The flatness is measured in the crisscross direction as follows. That is, the height of the surface of ingot 10 is measured at a plurality of positions (measurement points) arranged in a crisscross direction with a 5-mm pitch (preferably in a matrix with a 5-mm pitch) from the center of the surface of ingot 10. Then, the difference in heights between adjacent measurement points is calculated. Further, from a tangent (tan) determined from the difference in heights and the distance between the measurement points, an angle corresponding to a tilt of the surface of the ingot (tilt angle) between the adjacent measurement points is determined.

Manufacture of Substrates:

After the measurement of the surface shapes as described above, the ingots in the example and the comparative example were formed into a cylindrical shape. Then, each of the ingots was sliced with a wire saw in a direction along the surface of the base substrate, to manufacture a silicon carbide substrate. The substrate had a thickness of 400 μm to 500 μm. After the slicing, both surfaces of the silicon carbide substrate were subjected to a mirror polishing process. Consequently, the silicon carbide substrate had a thickness of 350 μm to 420 μm.

Measurement of Nitrogen Concentration:

For the substrates thus made, nitrogen concentrations in a region located below the (0001) facet of the ingot and having a relatively high nitrogen concentration (high concentration nitrogen region) and in the remaining region were measured. The measurements were made with SIMS (Secondary Ion Mass Spectrometry). A measured thickness was set to 10 μm in order to suppress measurement variation.

Measurement of Transmittance:

For the substrates thus made, light transmittances through the high concentration nitrogen region and through the remaining region were measured. A transmittance of light having a wavelength within a range from 400 nm to 500 nm through each region was measured with a visible light spectrometer.

Measurement of Dislocation Density:

For the substrates thus made, dislocation density of the surface was measured. Specifically, the measurement was made as follows. First, the silicon carbide substrate was immersed for 1 to 10 minutes in a molten salt KOH solution heated to 500° C. Then, the number of formed pits was counted by observation of the surface of the silicon carbide substrate with a Nomarski differential interference microscope. It is preferable to count the number by taking a mapping picture of the entire surface, counting the total number of pits, and calculating an average density per unit area. When a silicon carbide substrate having a diameter of 2 inches is used, for example, an average density of pits at five or more measurement points may be adopted as a pit density, by counting the number of pits per unit area at a total of five points including the central portion of the substrate and positions at a distance of about 18 mm from the central portion in a crisscross direction, and taking an average of them, for example. Each of the evaluated silicon carbide substrates was a substrate in a position at a distance of 20 mm from the uppermost surface of the base substrate of the prepared ingot, and a comparison was made with data of the base substrate.

(Results)

As to Ingots:

In the ingots in the example, a (0001) facet was arranged on the uppermost surface at the end portion (end portion on the upstream side) in the off angle direction of the base substrate. The width of the (0001) facet in the off angle direction when viewed two-dimensionally was 12.5 mm with an ingot diameter of 163 mm, 11 mm with an ingot diameter of 115 mm, and 5.5 mm with an ingot diameter of 63 mm. An average value of the height of the ingot was 13 mm with an ingot diameter of 163 mm, 8 mm with an ingot diameter of 115 mm, and 4 mm with an ingot diameter of 63 mm. The tilt angle indicating the flatness of the surface was equal to or less than 10° on average in each case, indicating a sufficient degree of flatness.

In the ingots in the comparative example, on the other hand, a (0001) facet was generated in the central portion of the uppermost surface of the ingot. The width of the (0001) facet in the off angle direction was within a range from 12% to 45% of the ingot diameter. The tilt angle indicating the flatness of the surface was more than 10° on average.

As to Substrates:

In the substrates cut from the ingots in the example, a high concentration nitrogen region having a relatively high nitrogen concentration was formed in a region located below the (0001) facet (region positioned at the end portion of the substrate). The position of the high concentration nitrogen region was substantially the same as the position of the facet. The width of the high concentration nitrogen region, while being distributed in a height direction of the ingot, was within a range from 3 to 9.5% relative to the ingot diameter.

In the substrates cut from the ingots in the comparative example, too, a high concentration nitrogen region was formed in a region located below the (0001) facet (region positioned in the central portion of the substrate). The position of the high concentration nitrogen region was substantially the same as the position of the facet in the comparative example, too. The size of the high concentration nitrogen region was distributed in the height direction of the ingot, and the width of the high concentration nitrogen region was within a range from 5 to 45% relative to the ingot diameter. The width (size) of the high concentration region was equal to or less than 10% of the ingot diameter in the comparative example too, but only in a region at a distance of 5 mm or less from the surface position of the base substrate. This is because the flatness of the surface of the grown silicon carbide is relatively maintained in this area since the total amount of grown silicon carbide is still small, and this is a result different from that in the example where the flatness is always maintained during crystal growth.

As to Nitrogen Concentration:

In the substrates in the example, the high concentration nitrogen region had a nitrogen concentration of 1.2 E19 cm⁻³, and the remaining region had a nitrogen concentration of 8 E18 to 1 E19 cm⁻³. Nitrogen concentrations in arbitrary five points in the region other than the high concentration nitrogen region were within a range of 20% relative to an average concentration of these five points.

In the substrates in the comparative example, the high concentration nitrogen region had a nitrogen concentration of 1.2 E19 cm⁻³, and the remaining region had a nitrogen concentration of 8 E18 to 1 E 19 cm⁻³.

As to Transmittance:

In the substrates in the example and the comparative example, the transmittance of light having a wavelength of 400 nm to 500 nm through the high concentration nitrogen region was 10 to 20%. The transmittance through the remaining region in the substrates was 25 to 35%. In a silicon carbide substrate cut from an ingot lightly doped with nitrogen, which was different from those in the present experiment, the transmittance through the high concentration nitrogen region was 35 to 45%, and the transmittance through the remaining region was 45 to 65%. A refractive index of each of the silicon carbide substrates, which was obtained by calculation from wavelength characteristics of the transmittance, was 2.5 to 2.8 in both examples.

As to Dislocation Density:

Measurements were made on substrates obtained by slicing the ingots in a position at a distance of 20 mm from the base substrate. When the base substrate had a micropipe density (MPD) of 10 to 100 cm⁻² and an etch pit density (EPD) of 1 to 5 E4 cm⁻² as the dislocation densities, in the substrates in the example, both the MPD and EPD could be reduced to between ½ and 1/20 relative to those of the base substrate in the region other than the high concentration nitrogen region.

In the substrates in the comparative example, on the other hand, the MPD and EPD decreased or increased within a range from ½ to 2.5.

The present invention is applied particularly advantageously to methods for manufacturing a silicon carbide ingot and a silicon carbide substrate.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method of manufacturing a silicon carbide ingot, comprising the steps of:
preparing a base substrate made of single crystal silicon carbide and having an off angle of 0.1° or more and 10° or less in an off angle direction which is either a <11-20> direction or a <1-100> direction relative to a (0001) plane; and
growing a silicon carbide layer on a surface of said base substrate,
in said step of growing a silicon carbide layer, a region having a (0001) facet being formed on a surface of grown said silicon carbide layer at an end portion on an upstream side, the upstream side being a side where an angle of intersection between a <0001> direction axis of said base substrate and said surface of said base substrate in said off angle direction is an acute angle.

2. The method of manufacturing a silicon carbide ingot according to claim 1, wherein
in said silicon carbide layer after said step of growing a silicon carbide layer, a portion located below said region having said (0001) facet is a high concentration nitrogen region having a nitrogen concentration higher than in a portion other than said portion located below said region having said (0001) facet in said silicon carbide layer.

3. The method of manufacturing a silicon carbide ingot according to claim 2, wherein
a width of said high concentration nitrogen region in said off angle direction is equal to or less than 1/10 of a width of said base substrate in said off angle direction.

4. The method of manufacturing a silicon carbide ingot according to claim 2, further comprising the step of removing said high concentration nitrogen region.

5. The method of manufacturing a silicon carbide ingot according to claim 2, wherein
a transmittance of light having a wavelength of 450 nm or more and 500 nm or less per unit thickness through said high concentration nitrogen region is lower than a transmittance of said light per unit thickness through the portion other than said high concentration nitrogen region in said silicon carbide layer.

6. The method of manufacturing a silicon carbide ingot according to claim 1, wherein
a micropipe density of the portion located below said region having said (0001) facet is higher than a micropipe density of the portion other than said portion located below said region having said (0001) facet in said silicon carbide layer.

7. The method of manufacturing a silicon carbide ingot according to claim 1, wherein
a maximum radius of curvature of the surface of said silicon carbide layer after said step of growing a silicon carbide layer is equal to or more than three times of a radius of a circumscribed circle of a planar shape of said base substrate.

8. A method of manufacturing a silicon carbide substrate, comprising the steps of:
preparing a silicon carbide ingot using the method of manufacturing a silicon carbide ingot according to claim 1, wherein
in said step of preparing a silicon carbide ingot, in said silicon carbide layer after said step of growing a silicon carbide layer, a portion located below said region having said (0001) facet is a high concentration nitrogen region having a nitrogen concentration higher than in a portion other than said portion located below said region having said (0001) facet in said silicon carbide layer, said method further comprises the steps of:
removing said high concentration nitrogen region from said silicon carbide ingot; and
slicing said silicon carbide ingot after performing said step of removing said high concentration nitrogen region.

9. A silicon carbide ingot comprising:
a base substrate made of single crystal silicon carbide and having an off angle of 0.1° or more and 10° or less in an off angle direction which is either a <11-20> direction or a <1-100> direction relative to a (0001) plane; and
a silicon carbide layer formed on a surface of said base substrate,
a region having a (0001) facet being formed on a surface of grown said silicon carbide layer at an end portion on an upstream side, the upstream side being a side where an angle of intersection between a <0001> direction axis of said base substrate and said surface of said base substrate in said off angle direction is an acute angle.

10. The silicon carbide ingot according to claim 9, wherein
in said silicon carbide layer, a portion located below said region having said (0001) facet is a high concentration nitrogen region having a nitrogen concentration higher than in a portion other than said portion located below said region having said (0001) facet in said silicon carbide layer.

11. The silicon carbide ingot according to claim 10, wherein
a width of said high concentration nitrogen region in said off angle direction is equal to or less than 1/10 of a width of said base substrate in said off angle direction.

12. The silicon carbide ingot according to claim 10, wherein
a transmittance of light having a wavelength of 450 nm or more and 500 nm or less per unit thickness through said high concentration nitrogen region is lower than a transmittance of said light per unit thickness through the portion other than said high concentration nitrogen region in said silicon carbide layer.

13. The silicon carbide ingot according to claim 9, wherein
a micropipe density of the portion located below said region having said (0001) facet is higher than a micropipe density of the portion other than said portion located below said region having said (0001) facet in said silicon carbide layer.

14. The silicon carbide ingot according to claim 9, wherein
a maximum radius of curvature of the surface of said silicon carbide layer is equal to or more than three times of a radius of a circumscribed circle of a planar shape of said base substrate.

15. A silicon carbide substrate, obtained by slicing the silicon carbide ingot according to claim 9.

16. A silicon carbide substrate, obtained by slicing the silicon carbide ingot according to claim 10, after said high concentration nitrogen region was removed from said silicon carbide ingot.

17. The silicon carbide substrate according to claim 16, wherein
nitrogen concentration varies from an average value by equal to or less than 10%.

18. The silicon carbide substrate according to claim 16, wherein
dislocation density varies from an average value by equal to or less than 80%.

19. A silicon carbide substrate, comprising a high concentration nitrogen region, which has a nitrogen concentration relatively higher than in a remaining portion, formed at one end portion in either a <11-20> direction or a <1-100> direction.
